(19) United States
(12) Patent Application Publication
(10) Pub. No.: US 2026/0319008 A1
(43) Pub. Date: Oct. 15, 2026

(54) SEMICONDUCTOR DEVICE AND SYSTEM USING THE SAME

(71) Applicant: RENESAS ELECTRONICS CORPORATION, Tokyo (JP)

(72) Inventors: Joshiro WATANABE, Tokyo (JP); Tsuyoshi OTA, Tokyo (JP); Youhei KENGOYAMA, Tokyo (JP)

(21) Appl. No.: 19/567,996

(22) Filed: Mar. 16, 2026

(30) Foreign Application Priority Data
Apr. 10, 2025 (JP) 2025-065234

(51) Int. Cl. G01R 31/389; G01R 31/367; G01R 31/3842; G01R 31/396; H02J 7/80

(52) U.S. Cl. CPC G01R 31/389; G01R 31/367; G01R 31/3842; G01R 31/396; H02J 7/80

(57) ABSTRACT

A semiconductor device comprises: a charging/discharging control circuit configured to control charging and discharging of a battery cell; and a table storing information on an internal resistance of the battery cell used for calculating SPC data of the battery cell. The semiconductor device acquires the values of the internal resistance of the battery cell at a plurality of different time periods, updates the table based on the acquired values of the internal resistance, and calculates the SPC data.

### CROSS-REFERENCE TO RELATED APPLICATION

The disclosure of Japanese Patent Application No. 2025-065234 filed on Apr. 10, 2025, including the specification, drawings and abstract is incorporated herein by reference in its entirety.

### BACKGROUND

The present invention relates to a semiconductor device and a system using the same, and relates to, for example, a semiconductor device mounted on a battery pack and a system with the battery pack mounted thereon.

A battery cell (simply referred to as battery below) is mounted on the battery pack, and the battery pack is used in, for example, a system such as laptop computer.

In the battery pack, the largest amount of power suppliable to the system changes depending on, for example, a charging state of the battery. For example, when the system temporarily executes a high-load processing, the battery pack transmits the largest amount of suppliable power to the system in order to prevent the system from being shut down, and the system executes the processing with a capability based on the transmitted largest amount of power. Thereby, the system can temporarily execute the high-load processing while being prevented from being shut down.

In the battery pack, a dynamic battery power technology (DBPT) that is one of the allowable current load calculation algorithms is exemplified as a technology playing a role for transmitting the largest amount of suppliable power to the system.

There is disclosed techniques listed below.

[Patent Document 1] Japanese Unexamined Patent Application Publication No. 2020-150708

An exemplary configuration for achieving DBPT is described in the Patent Document 1. The Patent Document 1 describes that a power supply capability value (power supply capability data) indicating the largest amount of suppliable power is calculated based on a battery internal resistance value estimated based on a battery voltage value measured by a voltage value measurement circuit and a battery current value measured by a current value measurement circuit.

### SUMMARY

However, the battery pack is practically used under various environments, and the power supply capability value may not be correctly calculated depending on the environment. Thus, a method for accurately calculating the power supply capability even under various environments has been awaited.

The outline of the typical aspects of the embodiments disclosed in the present application will be briefly described below.

A semiconductor device comprises: a memory circuit storing impedance information on a battery cell; and a control circuit controlling charging and discharging of the battery cell and calculating power supply capability data indicating a power supply capability of the battery cell. The semiconductor device is configured to acquire an impedance of the battery cell at a plurality of different time periods, to update the impedance information stored in the memory circuit, based on an acquired plurality of the impedances, and to generate the power supply capability data based on the impedance information stored in the memory circuit.

Other objects and novel characteristics will become apparent from the description of the present specification and the accompanying drawings.

According to one embodiment, a semiconductor device capable of suppressing shut down can be provided.

### BRIEF DESCRIPTIONS OF THE DRAWINGS

FIG. 1 is a block diagram illustrating a configuration of a system according to a first embodiment.

FIG. 2A is a diagram illustrating an exemplary table according to the first embodiment.

FIG. 2B is a diagram illustrating an exemplary table according to the first embodiment.

FIG. 3 is a flowchart for explaining a step of updating MPC according to the first embodiment.

FIG. 4 is a flowchart for explaining a step of updating SPC according to the first embodiment.

FIG. 5A is a diagram for explaining steps according to the first embodiment.

FIG. 5B is a diagram for explaining steps according to the first embodiment.

FIG. 5C is a diagram for explaining steps according to the first embodiment.

FIG. 6 is a flowchart for explaining update of a table v2 according to the first embodiment.

FIG. 7 is a diagram for explaining update of the table v2 according to the first embodiment.

FIG. 8 is a flowchart for explaining update of a table v2 according to a second embodiment.

FIG. 9 is a diagram for explaining update of the table v2 according to the second embodiment.

FIG. 10A is a diagram for explaining update of the table v2 according to the second embodiment.

FIG. 10B is a diagram for explaining update of the table v2 according to the second embodiment.

FIG. 11 is a flowchart for explaining update of a table v2 according to a third embodiment.

FIG. 12 is a diagram for explaining update of the table v2 according to the third embodiment.

FIG. 13A is a diagram for explaining update of the table v2 according to the third embodiment.

FIG. 13B is a diagram for explaining update of the table v2 according to the third embodiment.

FIG. 14 is a flowchart for explaining update of a table v2 according to a fourth embodiment.

FIG. 15 is a diagram for explaining update of the table v2 according to the fourth embodiment.

FIG. 16 is a diagram for explaining update of the table v2 according to the fourth embodiment.

FIG. 17A is a diagram for explaining a fifth embodiment.

FIG. 17B is a diagram for explaining the fifth embodiment.

FIG. 18 is a flowchart for explaining update of a table v2 according to the fifth embodiment.

FIG. 19 is a diagram for explaining update of the table v2 according to the fifth embodiment.

FIG. 20 is a diagram illustrating an outline of a laptop computer with a battery pack mounted thereon.

FIG. 21A is a waveform diagram for explaining SPC that is a power supply capability value according to a comparative example of each embodiment.

FIG. 21B is a waveform diagram for explaining SPC that is a power supply capability value according to a comparative example of each embodiment.

### DETAILED DESCRIPTION

The following is explanation for each embodiment of the present invention with reference to drawings. Note that only one example is disclosed, and appropriate modification with keeping the idea of the present invention which can be easily anticipated by those who are skilled in the art is obviously within the scope of the present invention.

In the present specification and each drawing, similar elements to those described earlier for the already-described drawings are denoted with the same or similar reference characters, and detailed explanation for them is appropriately omitted in some cases.

### Comparative Example

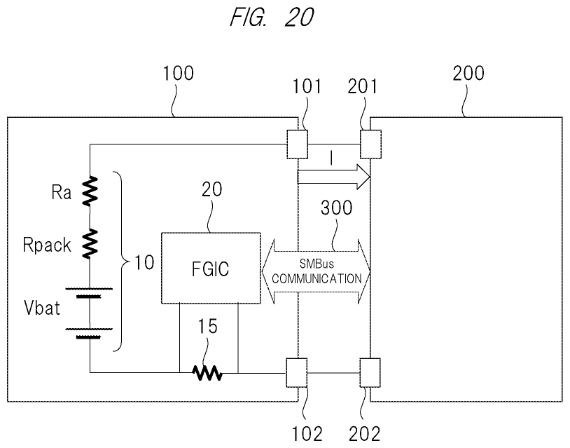

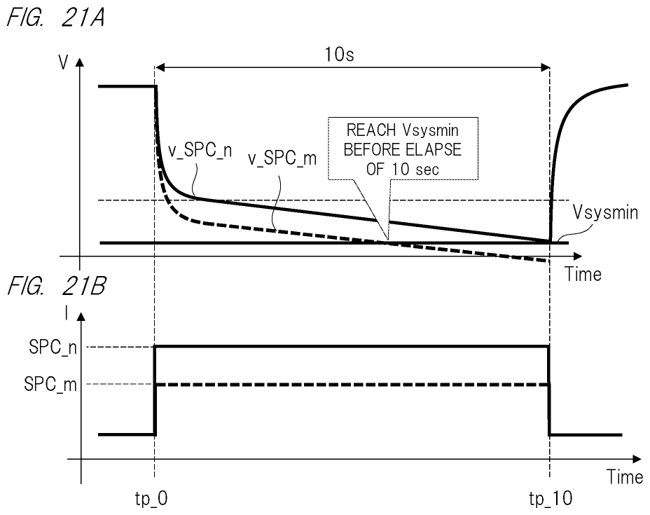

FIGS. 20, 21A, and 21B illustrate a comparative example of each embodiment studied by the present inventors. As the comparative example, a case in which a power supply capability value cannot be correctly calculated will be described.

FIG. 20 is a diagram schematically illustrating a laptop computer (also referred to as system or load below) 200 with a battery pack 100 mounted thereon. A positive power supply terminal 201 and a negative power supply terminal 202 of the laptop computer 200 are connected to a positive power supply terminal 101 and a negative power supply terminal 102 of the battery pack 100, respectively, and the laptop computer 200 is operated by a power supplied from the battery pack 100 via the positive power supply terminal and the negative power supply terminal.

The battery pack 100 includes a battery cell 10, a semiconductor device for battery control (fuel gauge IC (FGIC), simply referred to as semiconductor device below) 20 for controlling charging, discharging, and the like of the battery cell 10, and a current sense resistor 15. In the battery cell 10, a term “Vbat” indicates a secondary battery made of, for example, a lithium battery or the like. In the battery cell 10, a term “Rpack” indicates an equivalent resistance of the secondary battery Vbat, and a term “Ra” indicates an internal resistance of the secondary battery Vbat. In the secondary battery Vbat, the internal resistance Ra is caused by battery deterioration due to repeated charging and discharging, aging, or the like. The value of the internal resistance Ra is increased by the battery deterioration. the higher the internal resistance Ra is because of the battery deterioration, the lower the power supply capability value is.

Communication 300 is made via a bus such as system management bus (SMBus) between the semiconductor device 20 and the laptop computer 200. In order to correctly execute DBPT, the laptop computer 200 requests the semiconductor device 20 in the battery pack 100 to update the power supply capability value via the SMBus communication 300. The updated power supply capability values are provided from the semiconductor device 20 to the laptop computer 200 in response to the request, and DBPT is executed in the laptop computer 200.

The power supply capability value includes two types of power supply capability values. These values are MaxPeakPower/Current (MPP/MPC) and SusPeakPower/Current (SPP/SPC). The MPP/MPC indicates the maximum power/current enabling the laptop computer 200 as the system to stably operate without being shut down during 10 ms (milliseconds) from start of pulse discharging (that is a state in which a large current is supplied from the battery pack to the system at the time of the startup of the system, the time of return from a sleep mode, or the like) of the battery pack 100. Similarly, the SPP/SPC indicates the maximum power/current enabling the laptop computer (system) 200 to stably operate without being shut down during 10 s (seconds) from start of pulse discharging of the battery pack 100. 10 milliseconds is referred to as a first time period while 10 seconds is referred to as a second time period below.

The power supply capability value will be described while the SPC is exemplified. FIGS. 21A and 21B are waveform diagrams for explaining the power supply capability value SPC. FIG. 21A is a waveform diagram illustrating a decrease in the voltage of the battery pack over time, where the horizontal axis indicates the time period while the vertical axis indicates voltage V of the battery pack. FIG. 21B is a waveform diagram illustrating a change in SPC over time, where the horizontal axis indicates the time period while the vertical axis indicates current I of the battery pack. The current I illustrated in FIG. 21B corresponds to the value of SPC, and is calculated based on the voltage V of the battery pack and the internal resistance (Ra+Rpack). That is, a relation [SPC=“(the voltage of the battery pack)/(the internal resistance of the battery pack)” is established.

In FIG. 21A, a term “Vsysmin” indicates the minimum battery voltage enabling the laptop computer 200 to operate without being shut down. When the battery pack 100 starts pulse discharging at time period tp_0, the voltage decreases as illustrated in a voltage waveform of V_SPC_n. The battery current that brings the battery voltage to reach the minimum voltage Vsysmin after elapse of 10 seconds (time period tp_10) from the start (time period tp_0) of pulse discharging is “SPC_n”.

The power supply capability value is decreased by a deterioration in the battery. For example, when SPC decreases from SPC_n to SPC_m as illustrated in FIG. 21B, the battery voltage reaches the minimum voltage Vsysmin before the elapse of 10 seconds (tp_10) from the start (tp_0) of pulse discharging as illustrated with a voltage waveform of V_SPC_m in FIG. 21A, and thus, the laptop computer 200 may be shut down.

SPC is calculated based on the voltage and the internal resistance of the battery pack as described above. The internal resistance of the battery for each absolute state of charge of the battery is registered in a table of the battery pack. When 10-second pulse discharging is generated by the laptop computer 200, the battery pack finds a new value of the internal resistance based on the voltage and the current, and updates the value of the internal resistance registered in the table to the new value of the internal resistance.

The internal resistance of the battery for MPC is also registered in a table of the battery pack as similar to SPC. The difference therebetween is that when 10-millisecond pulse discharging shorter than 10-second pulse discharging is generated, the battery pack 100 finds the internal resistance and updates the internal resistance registered in the table for MPC to the new internal resistance.

If the laptop computer (system) generates 10-millisecond pulse discharging and 10-second pulse discharging at an appropriate frequency, the tables for MPC and SPC are appropriately updated, thereby preventing the system from being shut down.

However, under the practical use environment of the battery pack in the laptop computer, although 10-millisecond pulse discharging is generated at an appropriate frequency, 10-second pulse discharging that is longer is generated at a low frequency. Thus, this causes a problem in which the internal resistance for SPC registered in the table cannot be updated at an appropriate frequency. Since the internal resistance for SPC is not updated, the deterioration in the battery cannot be considered, and thus, the voltage of the battery pack is made lower than the minimum voltage Vsysmin before the elapse of 10 seconds from the start of pulse discharging, and thus, the laptop computer may be shut down.

In the above description, the current (SPC, MPC) is exemplified. However, the same goes for the power (SPP, MPP).

### First Embodiment

### <Configuration of System>

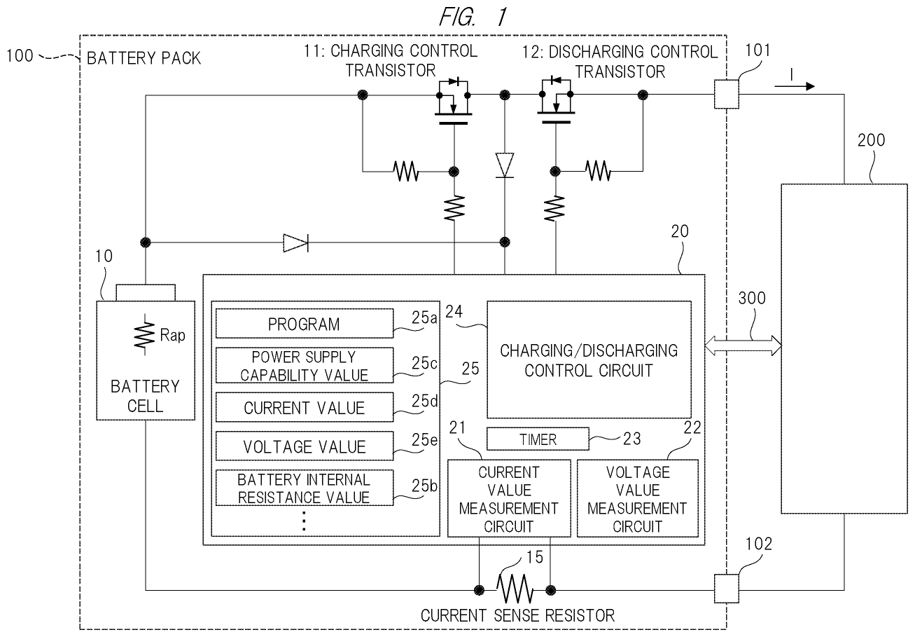

FIG. 1 is a block diagram illustrating a configuration of a system according to a first embodiment. The battery pack 100 is mounted on a laptop computer 200 as a system. In this description, the laptop computer 200 is exemplified as a system (load) to which a power is supplied from the battery pack, but the present disclosure is not limited to the example.

The battery pack 100 includes a battery cell 10, a charging control transistor 11, a discharging control transistor 12, a current sense resistor 15, a battery-control semiconductor device 20, a positive power supply terminal 101, a negative power supply terminal 102, and the like. As illustrated in FIG. 1, the positive power supply terminal 101 and the negative power supply terminal 102 are connected to the laptop computer 200 as the load, and the power is supplied from the battery pack 100 to the laptop computer 200 via the power supply terminals 101 and 102.

The battery cell 10 is made of a secondary battery such as lithium battery. The battery cell 10 may be made of a plurality of cells, or may be made of a single cell. A term “Rap” illustrated in the battery cell 10 indicates an internal resistance of the battery cell 10 made of a combination of the resistance Rpack and the resistance Ra illustrated in FIG. 20.

The charging control transistor 11 is a circuit element for executing current control mainly when the battery cell 10 is charged. The charging control transistor 11 is made of, for example, an N-channel field effect transistor. The gate of the charging control transistor 11 is connected to the semiconductor device 20 as illustrated in FIG. 1. The ON/OFF of the charging control transistor 11 is switched by gate voltage control of the semiconductor device 20.

The discharging control transistor 12 is a circuit element for executing current control when the battery cell 10 is discharged, in other words, when the power is supplied to the laptop computer 200. The discharging control transistor 12 is made of an N-channel field effect transistor. The gate of the discharging control transistor 12 is connected to the semiconductor device 20. The ON/OFF of the discharging control transistor 12 is switched by gate voltage control of the semiconductor device 20.

The current sense resistor 15 is a circuit element for detecting the current (load current) I supplied to the laptop computer 200. The current sense resistor 15 is connected to the semiconductor device 20, and the current value of the load current I is measured by a current value measurement circuit 21 (described later) provided in the semiconductor device 20.

The semiconductor device 20 includes the current value measurement circuit 21, a voltage value measurement circuit 22, a timer 23, a charging/discharging control circuit 24, a memory circuit 25, and the like as illustrated in FIG. 1.

The current value measurement circuit 21 is a circuit block for measuring the current value of the load current I flowing in the current sense resistor 15. The current value measurement circuit 21 includes, for example, a current value measurement circuit and an analog/digital (AD) converter. The current value measurement circuit 21 converts the current value of the load current I acquired in the current value measurement circuit to a digital current value by using the AD converter, and outputs the digitalized current value. The output current value is stored in, for example, a corresponding storage region in the memory circuit 25.

The voltage value measurement circuit 22 is a circuit block for measuring the voltage of the positive power supply terminal 101 of the battery pack 100, the voltage between the positive power supply terminal 101 and the negative power supply terminal 102, and the like. Note that the voltage value measurement circuit 22 may measure the inter-terminal voltage of the battery cell 10. At this time, the voltage value measurement circuit 22 may measure the inter-terminal voltage of each cell. The voltage value measurement circuit 22 includes, for example, a voltage value measurement circuit and an AD converter. The voltage value measurement circuit 22 converts the voltage value acquired in the voltage value measurement circuit to a digital voltage value by using the AD converter, and outputs the digitalized voltage value. The output voltage value is stored in, for example, a corresponding storage region in the memory circuit 25.

The timer (timing circuit) 23 starts a timing operation in response to, for example, the start of pulse discharging of the battery cell 10, and ends the timing operation when the pulse discharging stops. That is, the timer 23 measures time period taken for the power supply from the battery pack 100 to the laptop computer 200. The measured time information is supplied to the charging/discharging control circuit 24.

The memory circuit 25 is a functional block for storing various items of information on the battery pack 100, programs, and the like. The memory circuit 25 includes storage regions for storing a program 25a, a power supply capability value 25c, a current value 25d, a voltage value 25e, a battery internal resistance value 25b, and the like for the control of the battery pack 100 as illustrated in FIG. 1. The memory circuit 25 may be made of a flash memory, a register, or the like, or a combination of these components.

The charging/discharging control circuit 24 controls the battery pack 100 by using various items of information stored in the memory circuit 25 and the time information from the timer 23 in accordance with the program 25a stored in the memory circuit 25, and makes SMBus communication 300 while communicating with the laptop computer 200. The control for the battery pack 100 by the charging/discharging control circuit 24 includes calculation of the internal resistance value of the battery pack, calculation of the power supply capability values, and the like although described in detail later. Similarly, the SMBus communication 300 also includes a processing of providing the power supply capability values to the laptop computer 200 in response to a request from the laptop computer 200 although described in detail later.

<<Power Supply Capability Value 25c and Battery Internal Resistance Value 25b>>

The power supply capability value 25c according to the first embodiment is made of two types of power supply capability values that are MMP/MPC and SPP/SPC as described above. The charging/discharging control circuit 24 calculates the power supply capability values (MPP/MPC and SPP/SPC) by using the current value 25d, the voltage value 25e, and the battery internal resistance value 25b stored in the memory circuit 25.

A current value, which is measured by the current value measurement circuit 21 and is stored in a storage region in the memory circuit 25, is used for the current value 25d, and a voltage value, which is measured by the voltage value measurement circuit 22 and is stored in a storage region in the memory circuit 25, is used for the voltage value 25e. The current value measurement circuit 21 and the voltage value measurement circuit 22 timely execute measurements. Thus, the current value 25d and the voltage value 25e are timely updated.

The battery internal resistance value 25b is equivalent to the resistance value (impedance information) of the internal resistance Rap of the battery cell 10 illustrated in FIG. 1, and is stored in a table formed in a storage region of the memory circuit 25. For example, the charging/discharging control circuit 24 calculates MPC and SPC by dividing the voltage value 25e by the battery internal resistance value 25b stored in the table. The initial battery internal resistance value 25b is previously stored in the table, and is updated in response to a request.

When the laptop computer 200 requests the semiconductor device 20 to update the power supply capability values, the semiconductor device 20 updates the battery internal resistance value registered in the table, calculates the power supply capability values based on the battery internal resistance value 25b, the current value 25d and the voltage value 25e stored in the table, and provides the values to the laptop computer 200. The laptop computer 200 executes DBPT by using the provided power supply capability values.

### <<Table>>

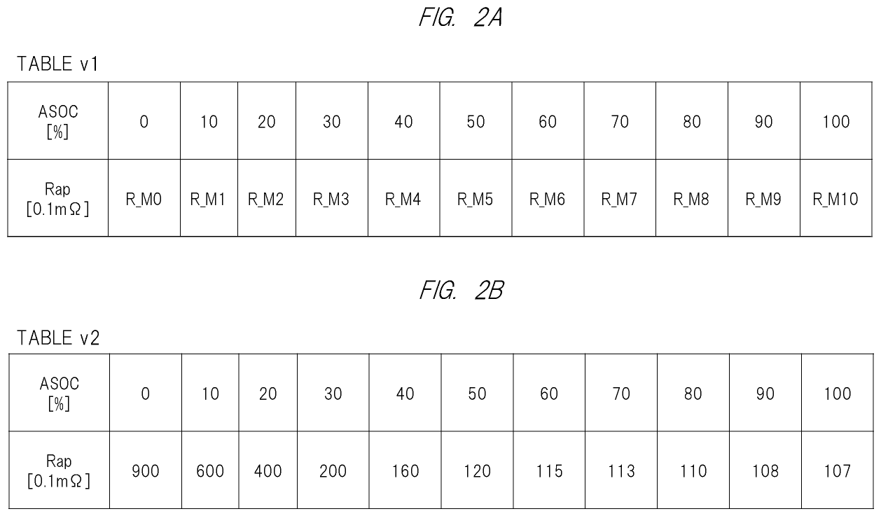

FIGS. 2A and 2B are diagrams illustrating exemplary tables according to the first embodiment. The tables illustrated in FIGS. 2A and 2B are formed in a storage region in the memory circuit 25. FIG. 2A illustrates a table (also referred to as table v1 or first table below) used for calculating MPC, and FIG. 2B illustrates a table (also referred to as table v2 or second table below) used for calculating SPC.

Although not particularly limited, in the first embodiment, the absolute state of charges (ASOC simply referred to as remaining charge below, unit: [%]) of the battery cell 10 and the values of the internal resistance Rap (unit: [0.1 mΩ]) of the battery corresponding to respective remaining charge are registered in the table v1 and the table v2. That is, 11 (0 to 10) remaining charges ASOC incrementing by 10% from 0% to 100% and 11 values of the internal resistance Rap corresponding to the 11 remaining charges ASOC are registered in each table. For example, when the remaining charges ASOC are 40%, 50%, and 60%, respectively, the values R_M4, R_M5, and R_M6 of the internal resistance Rap are registered in the table v1. To the contrary, when the remaining charges ASOC are 40%, 50%, and 60%, respectively, the values 160, 120, and 115 of the internal resistance Rap are registered in the table v2.

In the following, the internal resistance registered in the table v1 is also referred to as first impedance (first impedance information), and the internal resistance registered in the table v2 is also referred to as second impedance (second impedance information). The first impedance and the second impedance are also referred to as impedance (impedance information) when being collectively described.

### <Update of Power Supply Capability Value>

The step of updating the power supply capability value will be explained below with reference to the drawings. The step of updating the power supply capability value 25c when the laptop computer (system) 200 restores from the sleep mode will be described herein. The explanation will be made while the time of the restoration of the laptop computer 200 from the sleep mode is exemplified. However, the same goes for, for example, time of the start up of the system. The power supply capability values will be explained while MPC and SPC are exemplified.

### <<Update of MPC>>

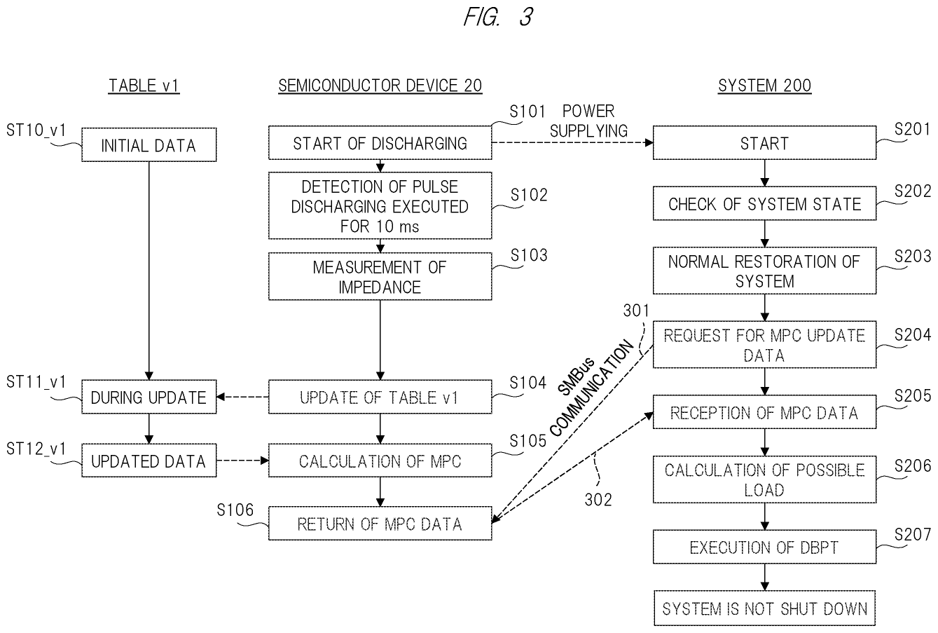

FIG. 3 is a flowchart for explaining the step of updating MPC according to the first embodiment. FIG. 3 illustrates the step at the time of the restoration of the system from the sleep mode. In FIG. 3, steps S101 to S106 are the steps achieved when the semiconductor device 20 executes the program 25a stored in the memory circuit 25, and steps S201 to S207 are the steps executed in the laptop computer 200. In FIG. 3, terms “ST10_v1” to “ST12_v1” indicate the states of the table v1 used for calculating MPC.

By an operation on a power supply button or the like when the system is in the sleep mode, the semiconductor device 20 starts step S101. In step S101, the semiconductor device 20 powers on the discharging control transistor 12 and the like. Thereby, power is supplied from the battery cell 10 (FIG. 1) to the positive power supply terminal 101 (FIG. 1), pulse discharging is started, and power is supplied from the battery pack 100 to the laptop computer 200.

When the power is supplied to the laptop computer 200, the laptop computer 200 starts in step S201, and checks the state of the system in step S202. If an abnormality is not detected by the checking in step S202, the laptop computer 200 as a system normally restores from the sleep mode in step S203.

Then, in step S204, the laptop computer 200 requests the semiconductor device 20 to update MPC data via SMBus communication 300 (step S301).

To the contrary, in step S102, the semiconductor device 20 detects 10-millisecond pulse discharging by using the timer 23 (FIG. 1). That is, the semiconductor device 20 detects whether pulse discharging is continued during 10 milliseconds from the start of pulse discharging in step S101, by using the timer 23. When 10-millisecond pulse discharging is detected in step S102, the semiconductor device 20 measures (calculates) the internal resistance (impedance) Rap of the battery cell 10 in step S103. The internal resistance Rap is calculated from, for example, the current value 25d and the voltage value 25e measured by the current value measurement circuit 21 and the voltage value measurement circuit 22.

Next, in step S104, the semiconductor device 20 updates the table v1. In the state ST10_v1 that is the initial state, predetermined initial data is registered in the table v1. That is, the predetermined initial data R_M0 to R_M10 is registered for the remaining charges ASOC of 0% to 100% illustrated in FIG. 2A, respectively. The semiconductor device 20 updates the table v1, based on the internal resistance Rap measured in step S103 (step S104). For example, the semiconductor device 20 updates the table v1 by changing the value of the internal resistance Rap corresponding to the remaining charge ASOC of predetermined % from the initial data (value) to the value measured in step S103. During the update of the table v1, the table v1 is in the during-update state ST11_v1. When the table v1 is completely updated, the updated value is registered in the table v1 (state ST12_v1).

When the table v1 is in state ST12_v1, in step S105, the semiconductor device 20 reads the internal resistance registered in the table v1 as the battery internal resistance value 25b, and calculates MPC based on the read battery internal resistance value 25b and the voltage value 25e.

In step S106, the semiconductor device 20 responds to the request (step S301) issued by the laptop computer 200 in step S204. That is, in step S106, the semiconductor device 20 provides the MPC calculated in step S105 as MPC data to the laptop computer 200 via the SMBus communication 300 (step S 302).

In step S205, the laptop computer 200 receives the MPC data provided in step S106. In step S206, the laptop computer 200 calculates a processing capability without shutdown or a load which can be applied to the system, based on the received MPC data. Next, DBPT is executed in step S207. By DBPT, a high-load processing is temporarily executed within a range not exceeding the load calculated in step S206. Thereby, the system is not shut down as illustrated after step S207.

### <<Update of SPC (Comparative Example)>>

It may be expected that SPC can be updated by the execution of the step similar to the step of updating MPC illustrated in FIG. 3. However, as described above, the frequency of the execution of 10-second pulse discharging is low depending on the practical use environment of the battery pack. Thus, the internal resistance for SPC is not updated, and there is the risk of the shut down of the system.

The step of updating SPC (comparative example) can be achieved by, for example, changing steps S102, S104 to S106, S204, and S205 illustrated in FIG. 3 to the steps for SPC and changing the table v1 to the table v2. That is, 10-second pulse discharging is detected in step S102, the table v2 is updated in step S104, and SPC is calculated and the SPC data is returned in steps S105 and S106. The SPC update data may be requested and the SPC data may be received in steps S204 and S205.

However, when 10-second pulse discharging is not generated, 10-second pulse discharging is not detected in step S102 for SPC. Thus, step S104 for SPC of updating the table v2 is not executed. Consequently, the table v2 is not updated, and the initial data registered in the table v2 is read in step S105 for SPC. In step S105 for SPC, SPC is calculated based on the not-yet-updated initial data, and thus, a possible load is calculated by using SPC based on the initial data in step S206 for SPC. Consequently, the system is shut down.

### <<Update of SPC>>

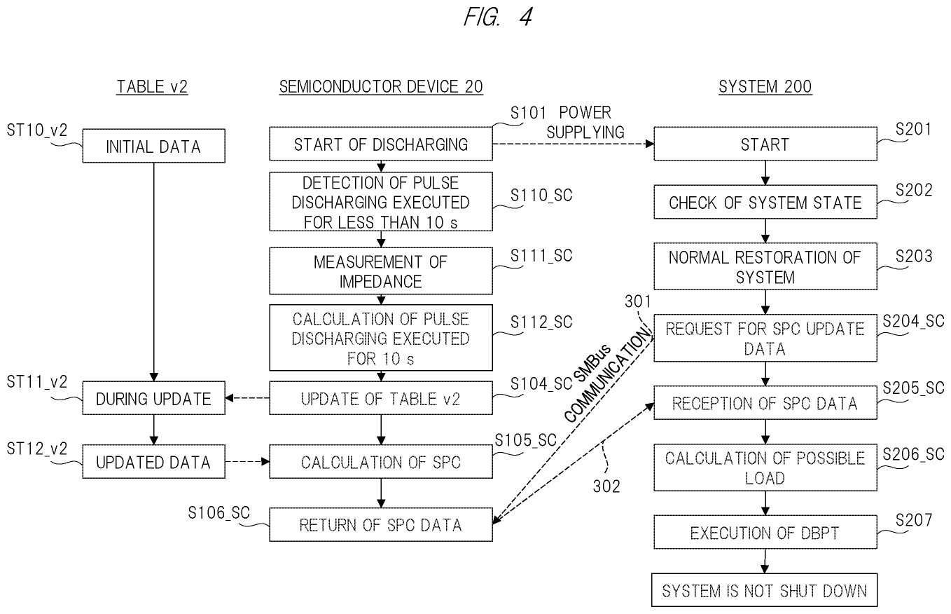

Next, the update of SPC according to the first embodiment will be described with reference to the drawings. FIG. 4 is a flowchart for explaining the step of updating SPC according to the first embodiment. FIG. 4 illustrates the step used when the system restores from the sleep mode as similar to FIG. 3. Since FIG. 4 is similar to FIG. 3, the differences therebetween will be mainly described. <<Table v2>>

FIG. 4 illustrates the table v2 used for calculating SPC instead of the table v1. In FIG. 4, ST10_v2 corresponds to state ST10_v1 in FIG. 3 and indicates an initial state in which predetermined initial data is registered. Similarly, ST11_v2 corresponds to state ST11_v1 in FIG. 3 and indicates a during-update state of the table v2, and ST12_v2 corresponds to state ST12_v1 in FIG. 3 and indicates a state in which the updated data has been already registered in the table v2.

### <<<Steps in System 200>>

The laptop computer (system) 200 executes steps S201 to S203, S207, and steps S204_SC to S206_SC. Steps S201 to S203 and S207 are the same as those in FIG. 3, and thus, the description thereof will be omitted. Steps S204_SC to S206_SC correspond to steps S204 to S206 in FIG. 3, and are steps for processing not MPC but SPC. That is, in step S204_SC, the system 200 issues a request for the SPC update data to the semiconductor device 20 via SMBus communication. The system 200 receives the SPC data provided from the semiconductor device 20 as a response to the request in step S205_SC, calculates the possible load by using the received SPC data in step S206_SC, and executes DBPT in step S207.

### <<<Steps in Semiconductor Device 20>>>

The semiconductor device 20 executes the program 25a stored in the memory circuit 25, thereby executing steps S101, S104_SC to S106_SC, and S110_SC to S112_SC. Step S101 is the same as step S101 in FIG. 3, and steps S104_SC to S106_SC are similar to steps S104 to S106 in FIG. 3. Steps S110_SC to S112_SC are added instead of steps S102 and S103 in FIG. 3.

In step S101, the battery pack 100 starts pulse discharging. When pulse discharging is started, in step S110_SC, the semiconductor device 20 detects pulse discharging executed for less than 10 seconds. That is, the semiconductor device 20 starts the timing operation by using the timer 23 in response to the start of pulse discharging in step S101. When pulse discharging is started, the semiconductor device 20 sets at least two time periods, time interval between which is more than 10 milliseconds and less than 10 seconds during the pulse discharging period, by using the timer 23. A time period closer to the start of pulse discharging among the two time periods is assumed to be first time period, and a time period at elapse of a predetermined time from the first time period among them is assumed to be second time period. In time series, the start time period of pulse discharging, the first time period, the second time period, and the end time period of pulse discharging come up in this order. When the duration from the start of pulse discharging to the end of pulse discharging is less than 10 seconds, the semiconductor device 20 determines that pulse discharging executed for less than 10 seconds is detected, in step S110_SC.

When it has been determined that pulse discharging executed for less than 10 seconds is detected in step S110_SC, the semiconductor device 20 measures the values of the internal resistance (impedance) Rap (FIG. 1) of the battery at the first time period and the second time period set in step S110_SC. That is, the semiconductor device 20 calculates the values of the internal resistance Rap of the battery based on the current value 25d and the voltage value 25e (FIG. 1) at the first time period and the second time period.

Next, in step S112_SC, the semiconductor device 20 converts the values of the internal resistance Rap measured at the first time period and the second time period in step S111_SC to the internal resistance value corresponding to 10-second pulse discharging. Steps S110_SC and S112_SC will be described in more detail later with reference to the drawings, and thus, are not further described herein.

Next, in step S104_SC, the semiconductor device 20 updates the table v2. In the state ST10_v2 as the initial state, the predetermined initial data is registered in the table v2. That is, the predetermined initial data 900 to 107 (0.1 mΩ) is registered for the remaining charges ASOC of 0% to 100% illustrated in FIG. 2B. The semiconductor device 20 updates the table v2 by using the values of the internal resistance Rap calculated in step S112_SC. For example, the semiconductor device 20 updates the resistance values of the internal resistance corresponding to the remaining charges ASOC of 0% to 100% in the table v2, based on the values of the internal resistance Rap calculated in step S112_SC. Note that the update of the table v2 will be also described in detail later with reference to the drawings. The table v2 during the update of the table v2 is in state ST11_v2, and the table v2 is in state ST12_v2 when the update is completed.

When the table v2 enters state ST12_v2, in step S105_SC, the semiconductor device 20 reads the internal resistance registered in the table v2 as the battery internal resistance value 25b, and calculates SPC based on the read battery internal resistance value 25b and the voltage value 25e. The semiconductor device 20 returns the calculated SPC as data to the system 200 via SMBus communication in step S106_SC.

The table v2 is updated in step S104_SC in the flowchart of FIG. 4, and thus, the system can be prevented from being shut down as illustrated after step S207.

### <<<Steps S110_SC to S112_SC>>>

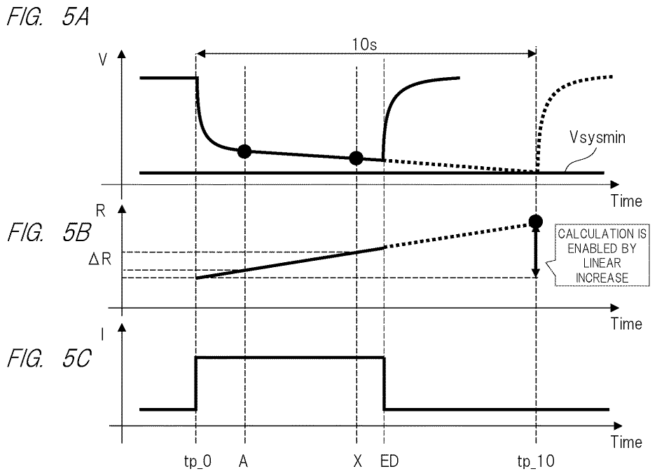

In steps S110_SC to S112_SC according to the first embodiment, even when pulse discharging of the battery is executed less than 10 seconds, the value of the internal resistance Rap of the battery corresponding to the value acquired at the time of the generation of 10-second pulse discharging can be calculated. FIGS. 5A, 5B, and 5C are diagrams for explaining the steps according to the first embodiment. FIG. 5A illustrates a change in the voltage of the battery cell 10 over time, where the vertical axis indicates the voltage of the battery cell 10. FIG. 5B illustrates a change in the internal resistance of the battery cell 10 over time, where the vertical axis indicates the resistance value. FIG. 5C illustrates a change in the current of the battery cell 10 over time, where the vertical axis indicates the current value.

The horizontal axis in each of FIGS. 5A to 5C indicates the time period. The battery cell 10 starts pulse discharging at time period tp_0 (step S101 in FIG. 4). The voltage of the battery cell 10 decreases as illustrated in FIG. 5A in response to the start of pulse discharging. In FIGS. 5A, 5B, and 5C, pulse discharging is ended at time period ED before time period tp_10 that is at elapse of 10 seconds (10 s) from the start (tp_0) of pulse discharging, by an operation of the power button or the like. During the pulse discharging period (from tp_0 to ED) as illustrated in FIG. 5C, the current value increases such that the current is supplied from the battery cell 10 to the load. When pulse discharging is ended at time period ED, the current decreases as illustrated in FIG. 5C, and the voltage of the battery cell 10 increases again as illustrated in FIG. 5A.

In FIG. 5B, the internal resistance is illustrated as the difference ΔR with respect to the resistance value acquired at the start of pulse discharging. Generally, it is known that the internal resistance (impedance) of the battery cell 10 is linearly increased after elapse of several seconds from the start of pulse discharging by polarization phenomenon. Thus, as illustrated in FIG. 5B, the internal resistance value of the battery cell 10 linearly increases over time after the start of pulse discharging. Therefore, the internal resistance value to be acquired after the elapse of 10 seconds can be calculated by extrapolation using a plurality of internal resistance values acquired at a plurality of time periods included in the pulse discharging period (from tp_0 to ED) shorter than 10 seconds.

In step S110_SC (FIG. 4), when detecting the pulse discharging period (from tp_0 to ED) executed for less than 10 seconds, the semiconductor device 20 sets a time period A (A seconds) in the pulse discharging period as the first time period, and a time period X (X seconds) as the second time period. Next, in step S111_SC, the semiconductor device 20 finds the internal resistance of the battery cell 10 acquired at the first time period (time period A) and the internal resistance of the battery cell 10 acquired at the second time period (time period X). In step S112_SC, the semiconductor device 20 calculates the internal resistance value of the battery cell 10 acquired at a time period tp_10 that is after the elapse of 10 seconds from the start tp_0 of pulse discharging by extrapolation using the internal resistance values found at the first time period and the second time period.

<<<Update of Table v2>>>

Next, exemplary update of the table v2 according to the first embodiment will be described with reference to the drawings.

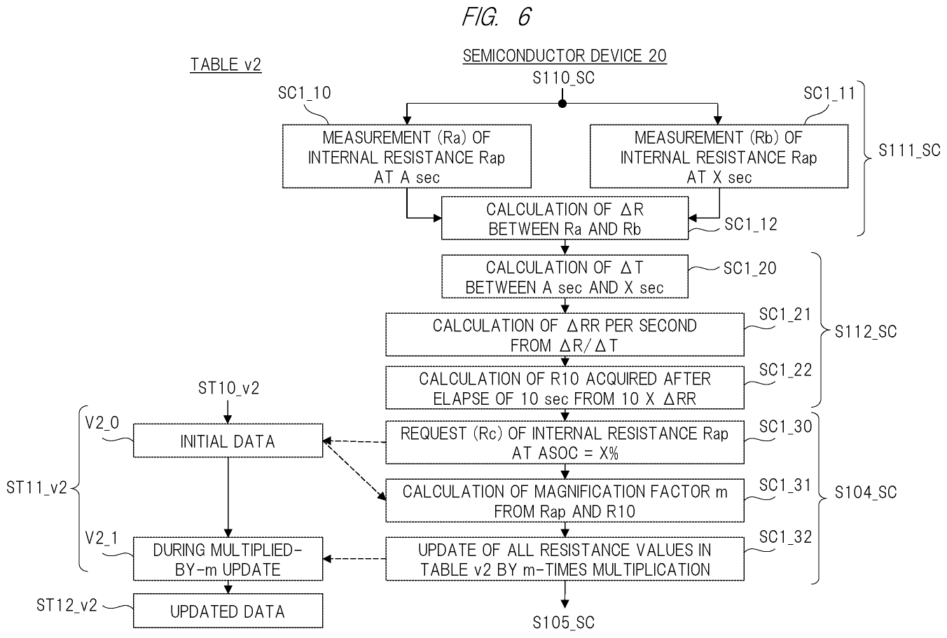

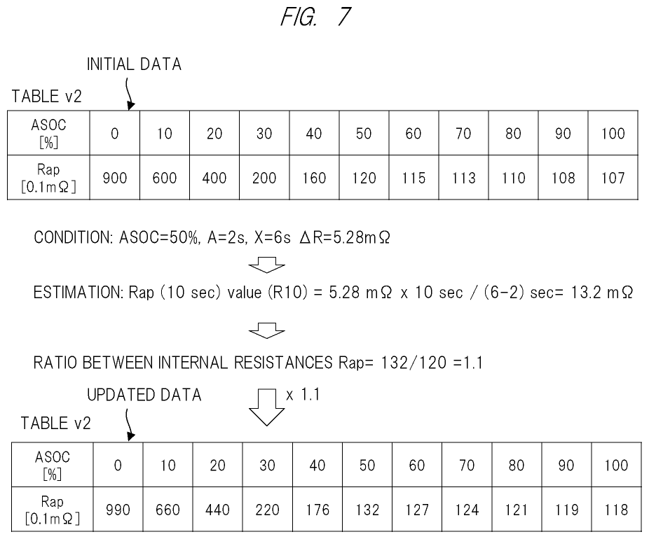

FIG. 6 is a flowchart for explaining the update of the table v2 according to the first embodiment. FIG. 7 is a diagram for explaining the update of the table v2 according to the first embodiment.

FIG. 6 illustrates details of steps S111_SC, S112_SC, and S104_SC among the steps illustrated in FIG. 4. FIG. 6 illustrates details of state ST11_v2 among the states illustrated in FIG. 4. That is, step S111_SC is made of steps SC1_10 to SC1_12, step S112_SC is made of steps SC1_20 to SC1_22, and step S104_SC is made of steps SC1_30 to SC1_32. State ST11_v2 is made of state V2_0 and state V2_1.

### <<<Steps S111_SC and S112_SC>>>

As described in FIGS. 4, 5A, 5B, and 5C, in step S110_SC, the semiconductor device 20 sets A seconds as the first time period and X seconds as the second time period. The semiconductor device 20 measures (calculates) the internal resistance Rap of the battery cell 10 at the first time period (A seconds) in step SC1_10, and measures (calculates) the internal resistance Rap of the battery cell 10 at the second time period (X seconds) in step SC1_11. The value of the internal resistance Rap measured (calculated) at the first time period is the value Ra, and the value of the internal resistance Rap measured (calculated) at the second time period is the value Rb. Next, in step SC1_12, the semiconductor device 20 calculates the difference (impedance difference) ΔR between the value Ra of the internal resistance Rap at the first time period and the value Rb of the internal resistance Rap at the second time period.

Next, in step SC1_20, the semiconductor device 20 calculates the temporal difference ΔT between the second time period (X seconds) and the first time period (A seconds). In step SC1_21, the semiconductor device 20 calculates the change (difference) ΔRR of the internal resistance Rap per unit time (1 second) by dividing the difference ΔR of the internal resistance Rap calculated in step SC1_12 by the temporal difference ΔT calculated in step SC1_20. Then, in step SC1_22, the semiconductor device 20 calculates the value R10 of the internal resistance Rap to be acquired after the elapse of 10 seconds (time period tp_10 in FIG. 5) from the start (time period tp_0 in FIG. 5) of pulse discharging by multiplying the difference ΔRR per unit time by 10.

The above steps will be described with reference to FIG. 7 by using exemplary specific numerical values. The upper side of FIG. 7 shows the table v2 in which the initial data is registered. In FIG. 7, the exemplary specific numerical values are illustrated as conditions below the table v2 in which the initial data is registered. That is, as the specific numerical values, the state of the remaining charge ASOC is 50%, the A seconds is 2 seconds, the X seconds is 6 seconds, the difference ΔR of the internal resistance Rap calculated in step SC1__12 is 5.28 mΩ.

When steps SC1_20 to SC1_22 are executed by using the specific numerical values, the value R10 of the internal resistance Rap to be acquired after elapse of 10 seconds is calculated as 13.2 mΩ as illustrated as estimation in FIG. 7.

### <<<Step S104_SC>>>

In step SC1_30, the semiconductor device 20 issues a request for the value of the internal resistance Rap corresponding to the remaining charge ASOC (X %) acquired in pulse discharging to the table v2.

In step SC1_31, the value of the internal resistance Rap corresponding to the remaining charge of X % is provided from the table v2 in response to the request in step SC1_30. In this case, the table v2 is in state V2_0 in which the initial data is registered, and thus, the value Rc of the internal resistance Rap corresponding to an initially-registered remaining charge of X % is provided from the table v2. The semiconductor device 20 calculates the ratio between the provided value Rc of the internal resistance Rap and the value R10 of the internal resistance Rap calculated in step SC1_22, and sets a magnification factor “m” as the calculated ratio.

Then, in step SC1_32, the semiconductor device 20 updates the table v2 by multiplying all the values of the internal resistance Rap registered in the table v2 by the magnification m. During this update, the table v2 is in multiplied-by-m during-update state V2_1.

The processing in step S104_SC will be described by using exemplary specific numerical values as similar to steps S111_SC and S112_SC. Since the state (X %) of the remaining charge ASOC is 50%, the value “Rc=120 (12.0 mΩ)” of the internal resistance Rap corresponding to the remaining charge of 50% is read from the table v2 (state V2_0) in response to the request in step SC1_30. In step SC1_31, the semiconductor device 20 calculates the ratio (132/120=1.1) between the resistance value R10 (13.2 mΩ=132) and the resistance value Rc (12.0 mΩ=120). The ratio 1.1 between the internal resistances is set as the magnification factor m.

Then, in step SC1_32, the semiconductor device 20 multiplies all the values of the internal resistance Rap corresponding to all the remaining charges ASOC (0% to 100%) registered in the table v2 by 1.1 set as the magnification factor m, and reregisters (updates) the values in the table v2. In the example of FIG. 7, the initial data is registered in the not-yet-updated table v2, and thus, the internal resistance values of the initial data are multiplied by 1.1, and the multiplied values are reregistered. For example, the values Rc=900, 120, 107 of the internal resistance Rap corresponding to the remaining charges ASOC=0%, 50%, 100% are multiplied by 1.1, and the multiplied values are reregistered as 990, 132, 118, respectively.

As described above, even if the pulse discharging period executed from its start is less than 10 seconds, the internal resistance Rap to be acquired after elapse of 10 seconds can be calculated, and the table v2 can be updated. Consequently, the system can calculate an appropriate possible load in step S206_SC (FIG. 4), and can be prevented from being shut down. All the values of the internal resistance registered in the table v2 are updated, and thus, the possible load can be appropriately calculated for any remaining charge of the battery cell.

The case of the remaining charge of 50% has been exemplified and described here. However, the present disclosure is not limited to the case. The SPC has been exemplified and described here. However, the same goes for SPP.

### Second Embodiment

In the first embodiment, the description has been made in the case using two internal resistance values measured at two different time periods (A and X) for one remaining charge ASOC (X %). In a second embodiment, description will be made in a case using four internal resistance values measured at two different time periods (A and X) for two different remaining charges ASOC (a first remaining charge of X1% and a second remaining change of X2%). The two remaining charges will be exemplified and described here. However, the present disclosure is not limited to this case, and three or more different remaining charges may be used.

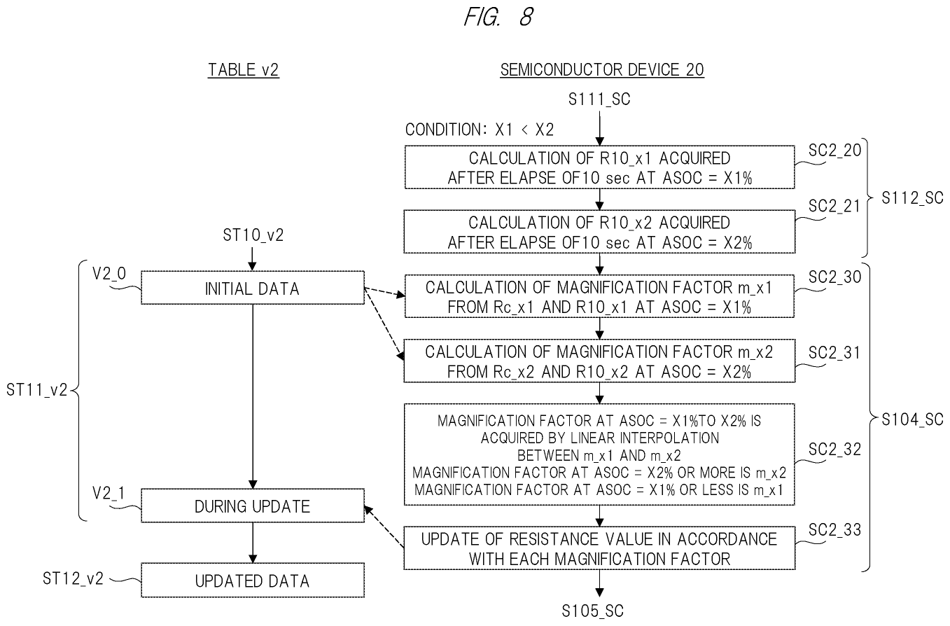

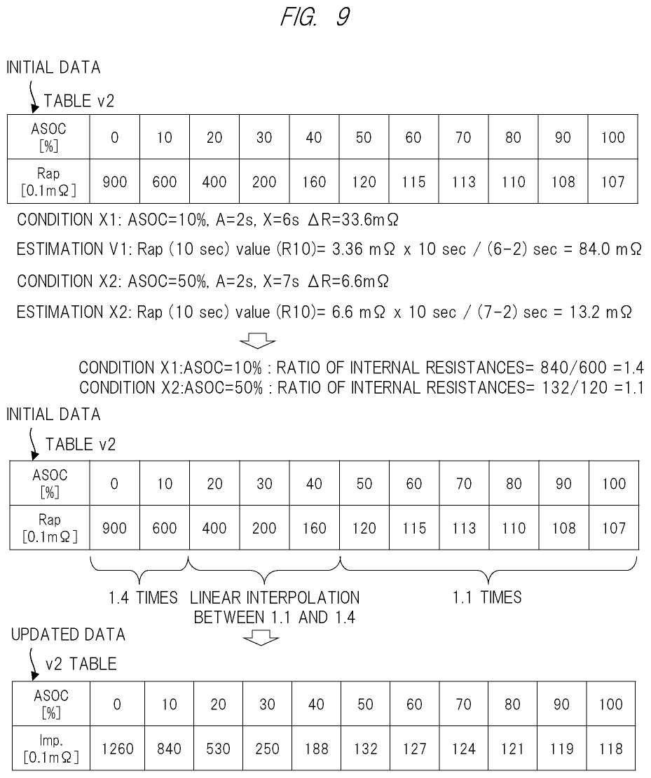

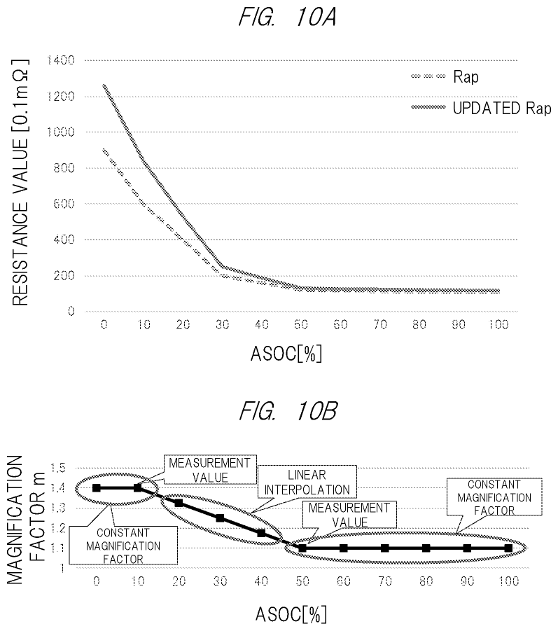

FIG. 8 is a flowchart for explaining the update of the table v2 according to the second embodiment. FIGS. 9, 10A, and 10B are diagrams each for explaining the update of the table v2 according to the second embodiment.

FIG. 8 illustrates details of steps S112_SC and S104_SC among the steps illustrated in FIG. 4. FIG. 8 illustrates details of state ST11_v2 among the states illustrated in FIG. 4. That is, step S112_SC is made of steps SC2_20 and SC2_21, and step S104_SC is made of steps SC2_30 to SC2_33. State ST11_v2 is made of state V2_0 and state V2_1. State V2_0 and state V2_1 are similar to those in FIG. 6, and thus, the description thereof will be omitted.

### <Step S111_SC>

Although not illustrated in detail in FIG. 8, in step S111_SC, steps SC1_10 to SC1_12 illustrated in FIG. 6 are executed on the internal resistance Rap of the battery cell 10 at a remaining charge ASOC of X1%. In step S111_SC, steps SC1_10 to SC1_12 illustrated in FIG. 6 are executed to the internal resistance Rap of the battery cell 10 at a remaining charge of X2% larger than the remaining charge of X1%. Thereby, the difference ΔR (ΔR_X1) between the internal resistances at the remaining charge ASOC of X1% and the difference ΔR (ΔR_X2) between the internal resistances at the remaining charge ASOC of X2% are calculated in step S111_SC, and step SC112_SC illustrated in FIG. 8 is executed.

### <Step S112_SC>

In step SC2_20, the semiconductor device 20 calculates the change ΔRR per unit time based on the temporal difference between the first time period A and the second time period X and the difference ΔR_X1, and multiplies the change ΔRR by 10, thereby calculating the resistance value R10_x1 of the internal resistance Rap to be acquired after the elapse of 10 seconds from the start of pulse discharging at the remaining charge ASOC of X1%. In step SC2_21, the semiconductor device 20 executes the calculation similar to step SC2_20 to the difference ΔR_X2, thereby calculating the resistance value R10_x2 of the internal resistance Rap to be acquired after the elapse of 10 seconds from the start of pulse discharging at the remaining charge ASOC of X2%.

### <Step S104_SC>

In step SC2_30, the semiconductor device 20 reads the resistance value Rc_x1 of the internal resistance Rap at the remaining charge ASOC of X1% from the table v2, and calculates the ratio between the resistance value Rc_x1 and the previously-calculated resistance value R10_x1 of the internal resistance Rap to calculate a magnification factor m_x1. Similarly, in step SC2_31, the semiconductor device 20 reads the resistance value Rc_x2 of the internal resistance Rap at the remaining charge ASOC of X2% from the table v2, and calculates the ratio between the resistance value Rc_x2 and the previously-calculated resistance value R10_x2 of the internal resistance Rap to calculate a magnification factor m_x2. That is, steps SC1_30 and SC1_31 illustrated in FIG. 6 are executed in steps SC2_30 and SC2_31, and the magnification factor m_x1 at the remaining charge of X1% and the magnification factor m_x2 at the remaining charge of X2% are calculated.

In step SC2_32, the semiconductor device 20 finds a magnification factor m at a remaining charge ASOC between X1% and X2% by using linear interpolation, and sets the magnification factor. A magnification factor m at a remaining charge of X1% or less is set as the magnification factor m_x1 at the remaining charge X1, and a magnification factor m at a remaining charge of X2% or more is set as the magnification factor m_x2 at the remaining charge X2.

In step SC2_33, the semiconductor device 20 updates the table v2 by updating the internal resistances Rap corresponding to the remaining charges ASOC of 0% to 100% by using the magnification factors set in step SC2_32.

### <Exemplary Specific Numerical Values>

A specific example using numerical values will be described with reference to FIGS. 9, 10A, and 10B as similar to FIG. 7. A case with the remaining charge (X1%) as 10% and the remaining charge (X2%) as 50% as illustrated in FIG. 9 will be explained. As illustrated in conditions X1, at the remaining charge of X1%, the first time period A is 2 seconds while the second time period X is 6 seconds. The difference ΔR (ΔR_X1) between the internal resistances Rapin at this time is assumed to be 33.6 mΩ. The calculation corresponding to step SC2_20 is illustrated in estimation X1 in FIG. 9. By the calculation, the resistance value R10_x1 of the internal resistance Rap acquired after elapse of 10 seconds at the remaining charge (X1%) of 10% is 84 mΩ.

As illustrated in conditions X2 in FIG. 9, at the remaining charge of X2%, the first time period A is 2 seconds while the second time period X is 7 seconds. The difference ΔR (ΔR_X2) between the internal resistance Rap at this time is assumed to be 6.6 mΩ. The calculation corresponding to step SC2_21 is illustrated in estimation X2 in FIG. 9. By the calculation, the resistance value R10_x2 of the internal resistance Rap acquired after elapse of 10 seconds at the remaining charge (X 2%) of 50% is 13.2 mΩ.

In the initial data registered in the table v2, the resistance value Rc of the internal resistance Rap at the remaining charge of 10% (X1%) is 600 (60 mΩ) while the resistance value Rc of the internal resistance Rap at the remaining charge of 50% (X 2%) is 120 (12 mΩ). Thus, by execution of steps SC2_30 and SC2_31 illustrated in FIG. 8, as illustrated in FIG. 9, the internal resistance ratio at the remaining charge of 10% (X1%) is expressed as “840/600=1.4”, the internal resistance ratio at the remaining charge of 50% (X 2%) is expressed as “132/120=1.1”, the magnification factor m_x1 is 1.4, and the magnification factor m_x2 is 1.1.

Since the remaining charge (X1%) is 10% while the remaining charge (X2%) is 50%, 1.4 is set as the magnification factor for the remaining charge of 10% or less, and 1.1 is set as the magnification factor for the remaining charge of 50% or more as illustrated in FIG. 9. For a remaining charge between 20% and 40%, a magnification factor found by linear interpolation between two magnification factors 1.1 and 1.4, that is, a magnification factor between 1.1 and 1.4 is set.

The initial data registered in the table v2, that is, the values of the internal resistance Rap corresponding to the remaining charges of 0% to 100% are updated by using the magnification factor set for each remaining charge, and the updated values of the internal resistance are reregistered in the table v2. The bottom of FIG. 9 in the sheet shows the table v2 in which the updated data is reregistered.

FIG. 10A is a diagram illustrating a relationship between the remaining charge and the internal resistance of the battery cell, and FIG. 10B is a diagram illustrating a relationship between the remaining charge and the magnification factor set in step SC2_32 (FIG. 8).

As illustrated in FIG. 10B, the magnification factors m at the remaining charges of 10% and 50% are the magnification factors 1.4 and 1.1 of the measurement values, a magnification factor m at a remaining charge of less than 10% is the same as the magnification factor m at the remaining charge of 10%, and a magnification factor m at a remaining charge of more than 50% is the same as the magnification factor m at the remaining charge of 50%. To the contrary, a magnification factor m at a remaining charge more than 10% and less than 50% is defined by linear interpolation between two measurement values (at 10% and 50%). Thereby, in a range between the remaining charge more than 10% and the remaining charge less than 50%, the magnification factor m linearly changes between the two measurement values.

In FIG. 10A, a dashed line indicates a change in the internal resistance Rap based on the initial data registered in the table v2, and a solid line indicates a change in the internal resistance Rap based on the updated data registered in the table v2.

According to the second embodiment, the table v2 is updated by using the plurality of magnification factors based on the measurement values and the magnification factor acquired by linear interpolation between the plurality of magnification factors, and thus, the accuracy of the updated table v2 can be improved.

### Third Embodiment

In a third embodiment, a case using four internal resistance values measured at two different times (A and X) for two different remaining charges ASOC (X1% and X2%) as similar to the second embodiment will be described. The use of two remaining charges is an example, and the number of remaining charges is not limited to this example.

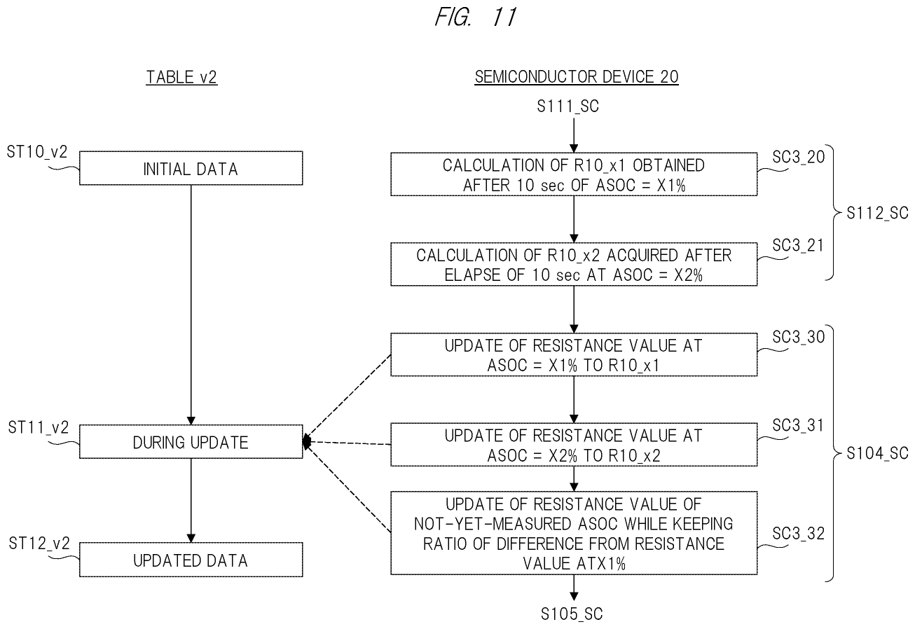

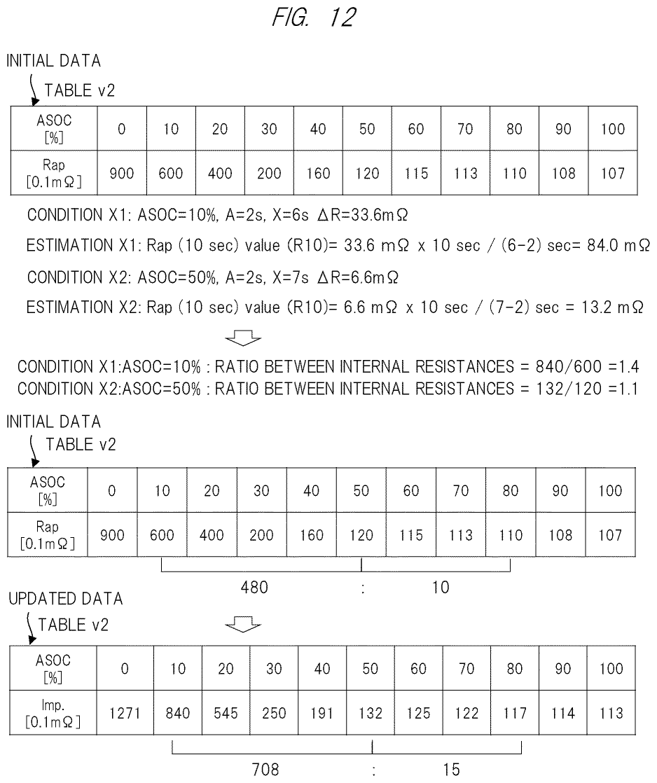

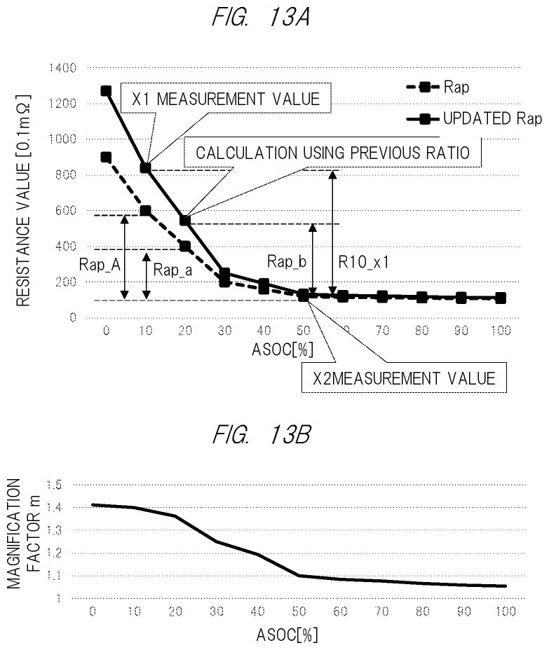

FIG. 11 is a flowchart for explaining the update of the table v2 according to the third embodiment. FIGS. 12, 13A, and 13B are diagrams each for explaining the update of the table v2 according to the third embodiment.

FIG. 11 illustrates details of steps S112_SC and S104_SC among the steps illustrated in FIG. 4. That is, step S112_SC is made of steps SC3_20 and SC3_21, and step S104_SC is made of steps SC3_30 to SC3_32.

### <Step S112_SC>

Steps SC3_20 and SC3_21 are the same as steps SC2_20 and SC2_21 illustrated in FIG. 8. That is, in step SC3_20, the semiconductor device 20 calculates the change ΔRR per unit time based on the temporal difference ΔT between the first time A and the second time X and the difference ΔR_x1, and multiplies the change ΔRR by 10, thereby calculating the resistance value R10_x1 of the internal resistance Rap to be acquired after the elapse of 10 seconds from the start of pulse discharging at the remaining charge ASOC of X1%. In step SC3_21, the semiconductor device 20 executes the calculation similar to step SC2_21 to the difference ΔR_x2. Thereby, the resistance value R10_x2 of the internal resistance Rap to be acquired after the elapse of 10 seconds from the start of pulse discharging at the remaining charge ASOC of X2% is calculated.

### <Step S104_SC>

In step SC3_30, the semiconductor device 20 updates the value of the internal resistance Rap at the remaining charge of X1% in the table v2 to the resistance value R10_x1 calculated in step SC3_20. Next, in step SC3_31, the semiconductor device 20 updates the value of the internal resistance Rap at the remaining charge of X2% in the table v2 to the resistance value R10_x2 calculated in step S3_21.

Then, in step SC3_32, the semiconductor device 20 calculates the value of the internal resistance Rap to be updated and acquired after elapse of 10 seconds at a not-yet-measured remaining charge, based on the resistance value R10_x1 calculated in step SC3_20, while keeping the ratio between the internal resistance Rap at a not-yet-updated remaining charge of X1% in step SC3_30 and the internal resistance Rap at the not-yet-updated remaining charge but to be updated. By using this calculated value of the internal resistance Rap to be acquired after elapse of 10 seconds, the internal resistance Rap at the not-yet-measured remaining charge but to be updated is updated. Step SC3_32 is repeatedly executed until there is no not-yet-measured and not-yet-updated remaining charge. Thereby, the updated data is registered in the table v2.

Although an example of step SC3_32 will be described later with reference to FIG. 13A, the internal resistance value at the not-yet-measured remaining charge (the resistance value to be acquired after elapse of 10 seconds) is calculated by multiplying the ratio between the not-yet-updated internal resistance value at a remaining charge of X1% and the (not-yet-updated) internal resistance value at the not-yet-measured remaining charge to be updated by the internal resistance value acquired after elapse of 10 seconds at the remaining charge of X 1%.

### <Specific Exemplary Numerical Value>

A specific exemplary numerical value will be described with reference to FIGS. 12, 13A, and 13B as similar to FIGS. 9, 10A, and 10B.

FIG. 12 is similar to FIG. 9. The initial data (table v2), conditions X1, X2, and estimations X1, X2 illustrated in FIG. 12 are the same as those in FIG. 9. FIG. 12 is different from FIG. 9 in that the ratio of the difference in the internal resistance between a remaining charge of 10% and a remaining charge of 50% to the difference in the internal resistance between a remaining charge of 50% and a remaining charge of 80% is clearly described as 480:10 and different therefrom in the values of the internal resistance in the updated data.

FIG. 13A is a diagram illustrating a relationship between the remaining charge and the internal resistance of the battery cell, and FIG. 13B is a diagram illustrating a relationship between the remaining charge and the ratio (magnification factor m) between the updated and not-yet-updated internal resistance values.

In FIG. 13A, a solid line indicates the updated internal resistance Rap, and a dashed line indicates the not-yet-updated internal resistance Rap. A term indicated as an X1 measurement value by a solid line indicates the value of the internal resistance Rap at a remaining charge of 10% calculated in step SC3_20, and a term indicated as an X2 measurement value indicates the value of the internal resistance Rap at a remaining charge of 50% calculated in step SC3_21. A term R10_x1 in FIG. 13A indicates the resistance difference between the value (X2 measurement value) of the internal resistance Rap at the remaining charge of 50% and the value (X1 measurement value) of the internal resistance Rap at the remaining charge of 10%.

In FIG. 13A, a term Rap_A with a dashed line indicates the resistance difference between the not-yet-updated value of the internal resistance Rap at a remaining charge of 50% and the not-yet-updated value of the internal resistance Rap at a remaining charge of 10%. Similarly, a term Rap_a indicates the resistance difference between the not-yet-updated value of the internal resistance Rap at a remaining charge of 50% and the not-yet-updated value of the internal resistance Rap at a remaining charge of 20%.

The explanation described here will be made in a case in which the ratio between the internal resistances Rap at different remaining charges are the same between the updated and not-yet-updated states. In exemplary explanation, it is assumed that the ratio between the resistance difference (Rap_A) between the value of the internal resistance Rap at a remaining charge of 10% and the value of the internal resistance Rap at a remaining charge of 50% and the resistance difference (Rap_a) between the value of the internal resistance Rap at a remaining charge of 50% and the value of the internal resistance Rap at a remaining charge of 20% is the same between the updated and not-yet-updated states. As illustrated in FIG. 12, in the initial data (table v2), the value of the internal resistance Rap at a remaining charge of 50% is 120 (0.1 mΩ).

A case of calculation of a resistance difference Rap_b for the internal resistance Rap acquired after elapse of 10 seconds at a remaining charge of 20% in step SC3_32 will be explained. The resistance difference Rap_b indicates the resistance difference between the updated value of the internal resistance Rap at a remaining charge of 50% and the updated value of the internal resistance Rap at a remaining charge of 20%. In this case, the resistance difference Rap_b can be calculated from an equation “Rap_b=R10_x1×Rap_a/Rap_A”. The updated value of the internal resistance Rap at a remaining charge of 50% is added to the calculated resistance difference Rap_b, thereby calculating the value of the internal resistance Rap to be acquired after elapse of 10 seconds at a remaining charge of 20%. Note that the updated value of the internal resistance Rap at a remaining charge of 50% is 132 (0.1 mΩ) as illustrated in the updated data (table v2) of FIG. 12. Thus, the value of the internal resistance Rap to be acquired after elapse of 10 seconds at a remaining charge of 20% is calculated as 545 (0.1 mΩ).

The ratio (magnification factor m) between the updated and not-yet-updated internal resistances Rap changes depending on the ratio for the not-yet-updated internal resistance Rap, and thus, changes for each remaining charge as illustrated in FIG. 13B. As illustrated in the bottom of FIG. 12, the values of the updated data are different from those of the updated data of FIG. 9.

### Fourth Embodiment

In a fourth embodiment, the update of the table v2 in a case of measurement (calculation) of the internal resistance Rap at a remaining charge not registered in the table v2 will be described.

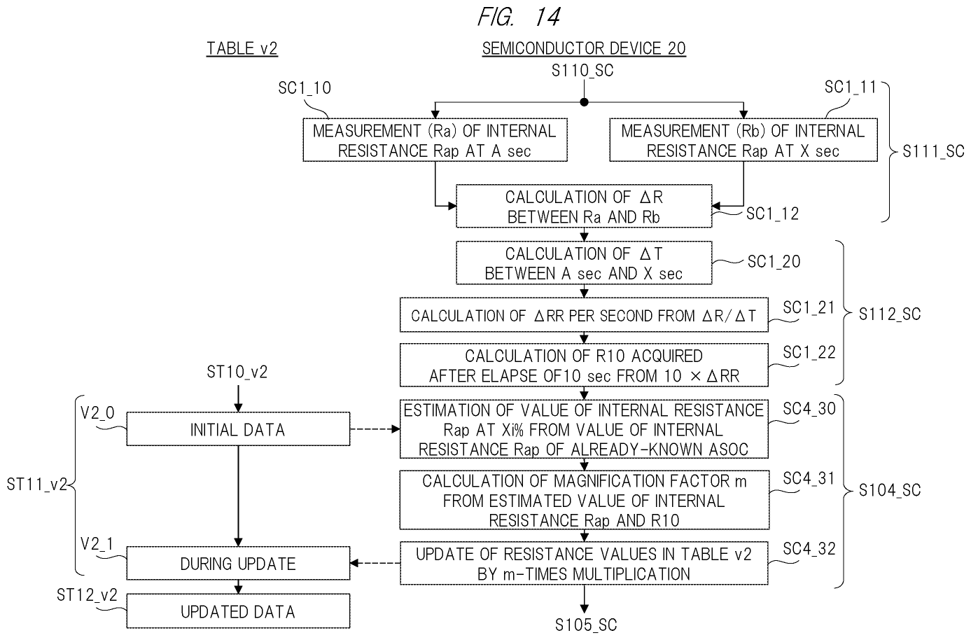

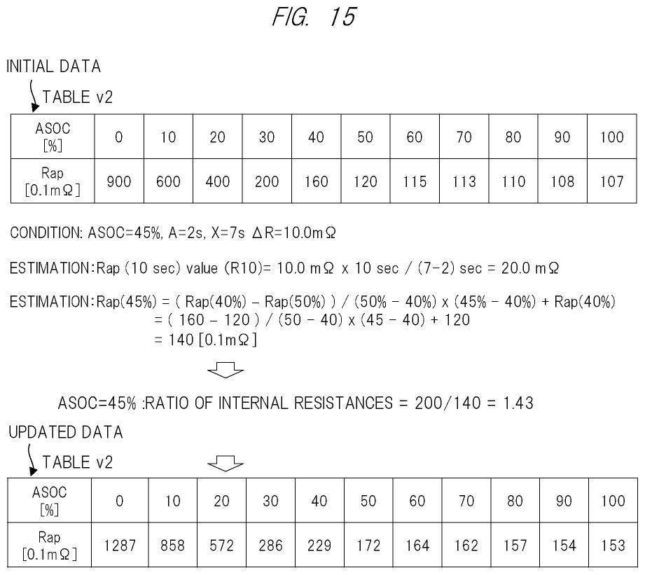

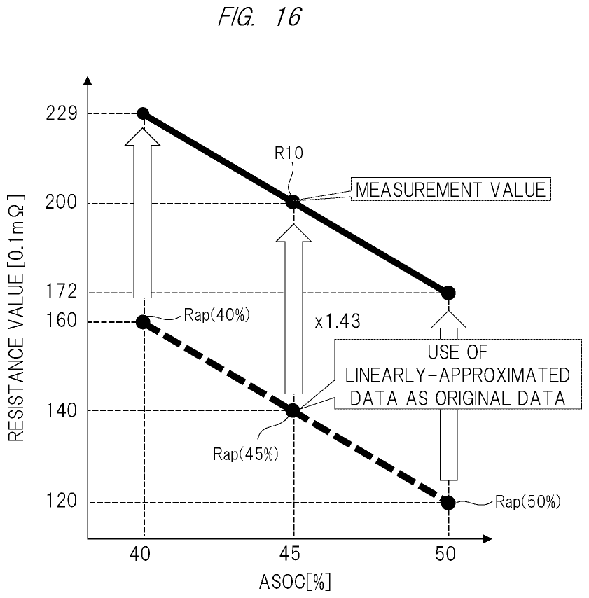

FIG. 14 is a flowchart for explaining the update of the table v2 according to the fourth embodiment. FIG. 15 and FIG. 16 are diagrams each for explaining the update of the table v2 according to the fourth embodiment.

FIG. 14 illustrates details of steps S111_SC, S112_SC, and S104_SC among the steps illustrated in FIG. 4. That is, step S111_SC is made of steps SC1_10 to SC1_12, step S112_SC is made of steps SC1_20 to SC1_22, and step S104_SC is made of steps SC4_30 to SC4_32.

### <Steps S111_SC and SC112_SC>

Steps SC1_10 to SC1_12 and SC1_20 to SC1_22 are similar to steps SC1_10 to SC1_12 and SC1_20 to SC1_22 illustrated in FIG. 6, and thus, the detailed description thereof will be omitted. FIG. 14 is different from the steps in FIG. 6 in that the internal resistance Rap of the battery cell at a remaining charge (Xi %) not registered in the table v2 is measured (calculated) at the first time (A seconds) and the second time (X seconds). Thereby, in step SC1_22 illustrated in FIG. 14, the resistance value R10 of the internal resistance Rap to be acquired after elapse of 10 seconds at a remaining charge of Xi % not registered in the table v2 is calculated.

### <Step S104_SC>

In step SC4_30, the semiconductor device 20 estimates the resistance value of the internal resistance Rap at a remaining charge of Xi % not registered in the table v2 from a value of an internal resistance Rap at an already-known remaining charge registered in the table v2. Next, in step SC4_31, the semiconductor device 20 finds the ratio between the estimated resistance value of the internal resistance Rap at a remaining charge of Xi % estimated in step SC4_30 and the resistance value R10 of the internal resistance Rap at a remaining charge of Xi % calculated in step SC1_22, and calculates the magnification factor m. Then, in step SC4_32, the semiconductor device 20 multiplies the resistance value of the internal resistance Rap at the remaining charge registered in the table v2 by the magnification factor m calculated in step SC4_31, and updates the resistance value. Thereby, the values of the internal resistance Rap at all the remaining charges registered in the table v2 can be updated based on the value of the internal resistance Rap at a remaining charge of Xi % not registered in the table v2.

As described later for an example, in step SC4_30, the semiconductor device 20 selects two adjacent remaining charges sandwiching the remaining charge of Xi %, as the already-known remaining charges.

### <Specific Exemplary Numerical Value>

A specific exemplary numerical value will be described with reference to FIG. 15 and FIG. 16. As illustrated as the specific exemplary numerical value in conditions in FIG. 15, the explanation described here will be made in a case in which the remaining charge (first remaining charge) (Xi %) is 45%, the first time (A seconds) is 2 seconds, the second time (X seconds) is 7 seconds, and the difference ΔR between the internal resistances Rap is 10.0 mΩ. As illustrated in FIG. 2B, the values of the internal resistance Rap at the remaining charges incrementing by 10% from 0% to 100% are registered in the table v2. Thus, the value of the internal resistance Rap at a remaining charge of 45% is not registered in the table v2. Two adjacent remaining charges (second remaining charge and third remaining charge) sandwiching the remaining charge of 45% and being registered in the table v2 are 40% and 50%, respectively.

By execution of step S112_SC, the resistance value R10 of the internal resistance Rap at a remaining charge of 45% is calculated as 20.0 mΩ (200 [0.1 mΩ]) as illustrated as estimation: Rap (10 sec) value (R10) in FIG. 15.

In step SC4_30, the semiconductor device 20 calculates the estimated Rap (45%) illustrated in FIG. 15. In the calculation, a remaining charge of 40% and a remaining charge of 50% indicate remaining charges sandwiching a remaining charge (first remaining charge) of 45%. Terms Rap (40%) and Rap (50%) in the not-yet-updated table v2 (initial table) indicate the internal resistance value (160) at a remaining charge (second remaining charge) of 40% and the internal resistance value (120) at a remaining charge (third remaining charge) of 50%, respectively. This calculation is for approximately calculating the internal resistance value Rap (45%) at a remaining charge of 45% by using linear interpolation between the internal resistance value Rap (40%) at a remaining charge of 40% and the internal resistance value Rap (50) at a remaining charge of 50% as illustrated in FIG. 16. The calculation in step SC4_30 is executed, thereby estimating the resistance value Rap (45%) of the internal resistance Rap at a remaining charge of 45% not registered in the table v2 as 140 [0.1 mΩ].

Next, in step SC4_31, the ratio between the internal resistances Rap is calculated. That is, the resistance value ratio (magnification factor m) between the resistance value “R10=200 [0.1 mΩ]” and the resistance value 140 [0.1 mΩ] is found as 1.43.

Then, the resistance values of the internal resistance Rap at the remaining charges incrementing by 10% registered in the table v2 are multiplied by the magnification factor m (1.43), and are reregistered in the table v2.

According to the fourth embodiment, even if the value of the internal resistance Rap at a remaining charge not registered in the table v2 is measured, the values of the internal resistance at all the remaining charges registered in the table v2 can be updated to the values to be acquired after the elapse of 10 seconds from the start of pulse discharging.

### Fifth Embodiment

In the first to fourth embodiments, the resistance values of the internal resistance Rap at two different times (A and X) are measured during the pulse discharging period (from tp_0 to ED) as illustrated in FIG. 5.

To the contrary, in a fifth embodiment, a case of measurement of the value of the internal resistance Rap at three or more time periods included in the pulse discharging period will be described. In the fifth embodiment, a change in the internal resistance Rap of the battery cell, which increases over time, is estimated by a polynomial equation, and a constant of the polynomial equation is found based on the measured values of the internal resistance Rap and the measurement time periods. A time period to be after elapse of 10 seconds from the start of pulse discharging is substituted into the polynomial equation involving the found constant, thereby calculating the value of the internal resistance Rap to be acquired after elapse of 10 seconds, and updating the table v2. The following explanation will be made while a quadratic equation is exemplified as the polynomial equation. However, the present disclosure is not limited thereto. That is, a higher-order polynomial equation may be used.

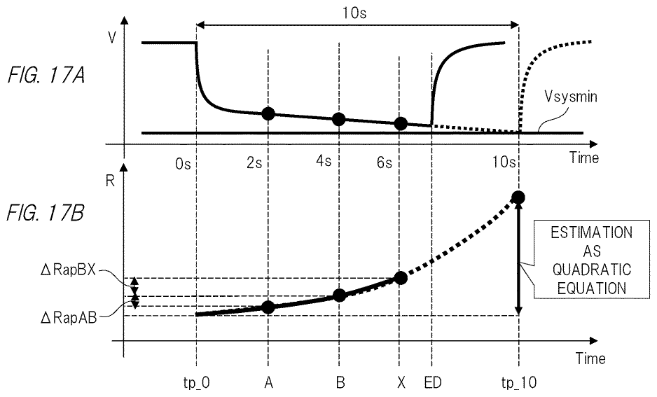

FIGS. 17A and 17B are diagrams each for explaining the fifth embodiment. FIGS. 17A and 17B are similar to FIGS. 5A and 5B. Also in FIG. 17A, the battery cell starts pulse discharging at time period tp_0, and ends the pulse discharging at time period ED as similar to FIG. 5A. In the fifth embodiment, the value of the internal resistance Rap of the battery cell is measured at three different time periods A, B, and X during the pulse discharging period (from tp_0 to ED). The time periods A, B, and X may be referred to as the first time period, the second time period, and the third time period, respectively, below. Although not particularly limited, the time period A is a time period after elapse of 2 seconds from the start of pulse discharging (tp_0), the time period B is a time period after elapse of 4 seconds from the start of pulse discharging, and the time period X is a time period after elapse of 6 seconds from the start of pulse discharging. In the fifth embodiment, as illustrated in FIG. 17B, the value of the internal resistance Rap of the battery cell is expressed by a quadratic curve passing through the internal resistance values measured at the time periods A, B, and X.

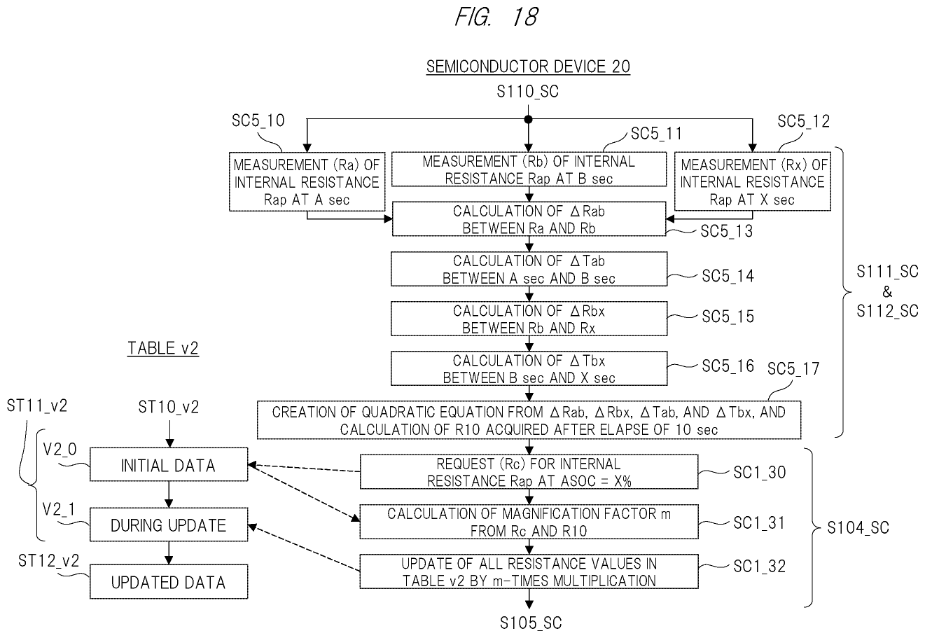

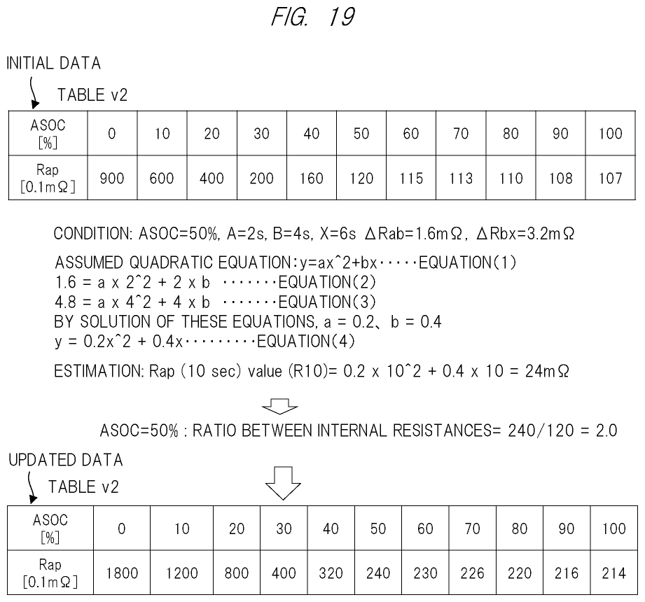

FIG. 18 is a flowchart for explaining the update of the table v2 according to the fifth embodiment. FIG. 19 is a diagram for explaining the update of the table v2 according to the fifth embodiment.

FIG. 18 illustrates details of steps S111_SC, S112_SC, and S104_SC among the steps illustrated in FIG. 4. FIG. 18 illustrates steps S111_SC and S112_SC as one step S111_SC & S112_SC. Step S111_SC & S112_SC is made of steps SC5_10 to SC5_17, and step S104_SC is made of steps SC1_30 to SC1_32.

### <Step S111_SC & S112_SC>

By executing steps SC5_10, SC5_11, and SC5_12, the semiconductor device 20 measures the value of the internal resistance Rap of the battery cell at the time period A first to acquire the resistance value Ra, and then, measures the value of the internal resistance Rap of the battery cell at the time period B to acquire the resistance value Rb, and further measures the value of the internal resistance Rap of the battery cell at the time period X to acquire the resistance value Rx.

Next, the semiconductor device 20 calculates, in step SC5_13, the difference (first-second impedance difference) ΔRab between the resistance values Ra and Rb acquired in the previous steps, and calculates, in step SC5_14, the temporal difference ΔTab between the time periods A and B. And, the semiconductor device 20 calculates, in step SC5_15, the difference (second-third impedance difference) ΔRbx between the resistance values Rb and Rx acquired in the previous steps, and calculates, in step SC5_16, the temporal difference ΔTbx between the time periods B and X.

Next, in step SC5_17, the semiconductor device 20 calculates the constant of the previously-assumed quadratic equation based on the differences ΔRab and ΔRbx and the temporal differences ΔTab and ΔTbx acquired in the previous steps, and substitutes the time period that is 10 seconds into the quadratic equation involving the calculated constant, thereby calculating the resistance value R10 of the internal resistance Rap to be acquired after elapse of 10 seconds.

### <Step S104_SC>

Step S104_SC is similar to that of FIG. 6. Thus, although not described in detail, the resistance value Rc of the internal resistance corresponding to the same remaining charge as the remaining charge acquired at the time of measurement of the internal resistance Rap is read from the not-yet-updated table v2, calculates the ratio (magnification factor m) between the resistance value Rc and the resistance value R10 of the internal resistance Rap calculated in step SC5_17, multiplies all the resistance values of the internal resistance Rap registered in the not-yet-updated table v2 by the magnification factor m, and updates the table v2.

### <Specific Exemplary Numerical Value>

A specific exemplary numerical value will be described with reference to FIG. 19. As illustrated as the specific exemplary numerical value in conditions in FIG. 19, the explanation described here will be made in a case in which the remaining charge is 50%, the first time period (A seconds) is 2 seconds, the second time period (B seconds) is 4 seconds, the third time period (X seconds) is 6 seconds, the difference ΔRab between the internal resistances Rap is 1.6 mΩ, and the difference ΔRbx is 3.2 mΩ. Although not illustrated in FIG. 19, the temporal difference ΔTab is 2 seconds (B seconds−A seconds), and the temporal difference ΔTbx is also 2 seconds (X seconds−B seconds).

In the fifth embodiment, it is estimated that the internal resistance Rap of the battery cell is based on the quadratic equation (y=ax²+bx) illustrated in FIG. 19. An equation (1) in FIG. 19 is acquired by the quadratic equation in which the difference ΔRab between the internal resistances Rap is substituted into the variable y while the temporal difference ΔTab is substituted into the variable x. An equation (2) in FIG. 19 is acquired by the quadratic equation in which the difference ΔRab+ΔRbx between the internal resistances Rap is substituted into the variable y while the temporal difference ΔTab+ΔTbx is substituted into the variable x. From the solution of the two quadratic equations, a constant “a” is 0.2 while a constant “b” is 0.4. An equation (4) is acquired by substituting the constant a=0.2 and the constant b=0.4 into the equation (1).

The resistance value R10 of the internal resistance Rap to be acquired after elapse of 10 seconds is calculated by substituting 10 (seconds) into the variable x in the equation (4).

The not-yet-updated resistance value of the internal resistance Rap at a remaining charge of 50% is acquired as 120 from the initial data of the table v2. Thus, the ratio (magnification factor m) between the resistance value R10 and the not-yet-updated value of the internal resistance Rap is 2.0.

All the values of the internal resistance registered in the not-yet-updated table v2 are multiplied by the magnification factor m, and the magnified values are reregistered.

According to the fifth embodiment, the value of the internal resistance Rap to be acquired after elapse of 10 seconds can be more correctly estimated, and the resistance values of the internal resistance registered in the updated table v2 can be made more correct.

Note that the explanations in the second to fifth embodiments have been made while SPC is exemplified. However, the same goes for SPP.

In the foregoing, the invention made by the inventors of the present application has been concretely described based on the embodiments. However, it is needless to say that the present invention is not limited to the foregoing embodiments, and various modifications can be made within the scope of the present invention.

What is claimed is:

1. A semiconductor device comprising:
a memory circuit configured to store impedance information on a battery cell; and
a control circuit configured to control charging and discharging of the battery cell and calculating power supply capability data indicating a power supply capability of the battery cell,
wherein the semiconductor device is configured:
to acquire an impedance of the battery cell at a plurality of different time periods;
to update the impedance information stored in the memory circuit, based on an acquired plurality of the impedances; and
to generate the power supply capability data based on the impedance information stored in the memory circuit.

2. The semiconductor device according to claim 1,
wherein the impedance information stored in the memory circuit comprises first impedance information used for calculating power supply capability data at a first time period, and second impedance information used for calculating power supply capability data at a second time period longer than the first time period,
wherein the memory circuit stores the first impedance information and the second impedance information as initial data, and
wherein the second impedance information is updated based on the acquired plurality of impedances.

3. The semiconductor device according to claim 2, further comprising:
a voltage measurement circuit configured to measure a voltage of the battery cell; and
a current measurement circuit configured to measure a current of the battery cell,
wherein the voltage and the current of the battery cell are measured at each of the plurality of time periods by the voltage measurement circuit and the current measurement circuit,
wherein the impedance of the battery cell at the plurality of time periods is calculated based on the measured voltage and the measured current, and
wherein the second impedance information is updated based on the calculated plurality of impedances.

4. The semiconductor device according to claim 3,
wherein the memory circuit comprises a first table and a second table,
wherein the first table stores a plurality of remaining charges of the battery cell and a plurality of items of the first impedance information corresponding to the plurality of remaining charges, and
wherein the second table stores a plurality of remaining charges of the battery cell and a plurality of items of the second impedance information corresponding to the plurality of remaining charges.

5. The semiconductor device according to claim 4,
wherein the plurality of time periods comprise a predetermined first time period and a second time period at which a predetermined time has elapsed from the first time period,
wherein the control circuit is configured:
to calculate an impedance difference between the impedance of the battery cell calculated at the first time period and the impedance of the battery cell calculated at the second time period;
to calculate a temporal difference between the first time period and the second time period; and
to update the second impedance information stored in the second table, based on the impedance difference and the temporal difference.

6. The semiconductor device according to claim 5,
wherein the plurality of remaining charges stored in the second table includes a first remaining charge and a second remaining charge different from the first remaining charge,
wherein the impedance difference is calculated at each of the first remaining charge and the second remaining charge,
wherein an impedance at the first remaining charge is acquired based on the calculated impedance difference at the first remaining charge and the temporal difference between the first time period and the second time period,
wherein an impedance at the second remaining charge is acquired based on the calculated impedance difference at the second remaining charge and the temporal difference between the first time period and the second time period,
wherein, in the second table, the second impedance information corresponding to a remaining charge equal to or less than the first remaining charge is updated based on the impedance at the first remaining charge, and the second impedance information corresponding to a remaining charge equal to or more than the second remaining charge is updated based on the impedance at the second remaining charge, and
wherein, in the second table, the second impedance information corresponding to a remaining charge between the first remaining charge and the second remaining charge is updated based on the impedance at the first remaining charge and the impedance at the second remaining charge.

7. The semiconductor device according to claim 6,
wherein the second table further stores a third remaining charge between the first remaining charge and the second remaining charge, and
wherein the second impedance information corresponding to the third remaining charge is updated based on an impedance acquired by linear interpolation between the impedance at the first remaining charge and the impedance at the second remaining charge.

8. The semiconductor device according to claim 5,
wherein the plurality of remaining charges stored in the second table comprises a first remaining charge and a second remaining charge different from the first remaining charge,
wherein the impedance difference is calculated at each of the first remaining charge and the second remaining charge,
wherein an impedance at the first remaining charge is calculated based on the impedance difference at the first remaining charge and the temporal difference between the first time period and the second time period,
wherein, in the second table, a ratio between an impedance expressed by stored impedance information corresponding to the first remaining charge and an impedance expressed by stored impedance information corresponding to the second remaining charge is acquired, and
wherein the second table is updated such that the stored impedance information corresponding to the second remaining charge expresses an impedance based on the acquired impedance at the first remaining charge and the acquired ratio.

9. The semiconductor device according to claim 5,
wherein the impedance difference is calculated at a first remaining charge not stored in the second table,
wherein a temporal difference between the first time period and the second time period is calculated,
wherein an impedance at the first remaining charge is calculated based on the impedance difference and the temporal difference,
wherein, in the second table, an impedance at the first remaining charge is estimated by linear approximation based on an impedance expressed by stored impedance information corresponding to a second remaining charge adjacent to the first remaining charge, at the second remaining charge, and an impedance expressed by stored impedance information corresponding to a third remaining charge adjacent to the first remaining charge, at the third remaining charge, and
wherein the impedance information stored in the second table is updated based on a ratio between the calculated impedance at the first remaining charge and the estimated impedance at the first remaining charge.

10. The semiconductor device according to claim 4,
wherein the plurality of time periods include a predetermined first time period, a second time period different from the first time period, and a third time different from the first time period and the second time period, and
wherein a constant of a polynomial equation for estimating an impedance of the battery cell is acquired by using a first-second impedance difference between an impedance of the battery cell calculated at the first time period and an impedance of the battery cell calculated at the second time period, a second-third impedance difference between an impedance of the battery cell calculated at the second time period and an impedance of the battery cell calculated at the third time period, and the first time period to the third time period,
wherein an impedance of the battery cell at the second time period is calculated by using the polynomial equation into which the acquired constant is substituted, and
wherein the second impedance information stored in the second table is updated.

11. A system comprising:
a battery cell; and
a semiconductor device capable of outputting power supply capability data of the battery cell,
wherein the semiconductor device comprises:
a memory circuit configured to store impedance information on the battery cell; and
a control circuit configured to control charging and discharging of the battery cell and calculating power supply capability data indicating a power supply capability of the battery cell, and
wherein the system is configured:
to acquire an impedance of the battery cell at a plurality of different time periods;
to update the impedance information stored in the memory circuit, based on an acquired plurality of the impedances; and
to generate the power supply capability data based on the impedance information stored in the memory circuit.

12. The system according to claim 11,
wherein the impedance information stored in the memory circuit comprises first impedance information used for calculating power supply capability data at a first time period, and second impedance information used for calculating power supply capability data at a second time period longer than the first time period,
wherein the memory circuit stores the first impedance information and the second impedance information as initial data, and
wherein the second impedance information is updated based on the acquired plurality of impedances.

13. The system according to claim 12,
wherein the semiconductor device includes:
a voltage measurement circuit configured to measure a voltage of the battery cell; and
a current measurement circuit configured to measure a current of the battery cell,
wherein the voltage and the current of the battery cell are measured at each of the plurality of time periods by the voltage measurement circuit and the current measurement circuit,
wherein the impedance of the battery cell at the plurality of time periods is calculated based on the measured voltage and the measured current, and
wherein the second impedance information is updated based on the calculated impedance.

14. The system according to claim 13,
wherein the memory circuit comprises a first table and a second table,
wherein the first table stores a plurality of remaining charges of the battery cell and a plurality of items of the first impedance information corresponding to the plurality of remaining charges, and
wherein the second table stores the plurality of remaining charges of the battery cell and a plurality of items of the second impedance information corresponding to the plurality of remaining charges.

15. The system according to claim 14,
wherein the plurality of time periods comprise a predetermined first time period and a second time period at which a predetermined time period has elapsed from the first time period,
wherein the control circuit is configured:
to calculate an impedance difference between the impedance of the battery cell calculated at the first time period and the impedance of the battery cell calculated at the second time period;
to calculate a temporal difference between the first time period and the second time period; and
to update the second impedance information stored in the second table, based on the impedance difference and the temporal difference.
